(19) United States
(12) Patent Application Publication
(10) Pub. No.: US 2023/0271227 A1
(43) Pub. Date: Aug. 31, 2023

(54) CLEANING JIG AND CLEANING METHOD

(71) Applicant: DISCO CORPORATION, Tokyo (JP)

(72) Inventor: Yunfeng YANG, Tokyo (JP)

(21) Appl. No.: 18/165,066

(22) Filed: Feb. 6, 2023

(30) Foreign Application Priority Data
Feb. 25, 2022 (JP) 2022-027707

(51) Int. Cl. B08B 3/02; B08B 5/02

(52) U.S. Cl. CPC B08B 3/02; B08B 5/02

(57) ABSTRACT

A cleaning jig for cleaning a chuck table including a porous member and a frame body with the porous member accommodated therein and exposed upwardly includes a main body, a surface, a groove, and a fluid drain passage. The main body has a front side, a back side, and a fluid supply passage extending from an inlet formed on the front side to an ejection orifice formed on the back side. The surface of the cleaning jig is formed on the back side of the main body such that, when the cleaning jig is placed on the chuck table upon cleaning the chuck table, the surface faces an upper surface of the porous member. The groove is formed around the ejection orifice on the back side of the main body. The fluid drain passage is formed through the main body, and communicates with the groove.

### BACKGROUND OF THE INVENTION

### Field of the Invention

The present invention relates to a cleaning jig to be arranged in a processing machine, which processes workpieces such as semiconductor wafers, and to be used to clean a chuck table including a porous member and to a cleaning method for cleaning the chuck table.

### Description of the Related Art

In manufacturing steps of device chips for use in electronic equipment such as mobile phones or computers, a plurality of devices such as integrated circuits (ICs) or large scale integration (LSI) circuits is first formed on a front surface of a semiconductor wafer. Next, the wafer is ground from a side of a back surface thereof to thin it to a predetermined thickness, is polished on the side of the back surface to planarize the back surface, and is then divided on a device-by-device basis to form individual device chips. A processing machine, such as a grinding machine, a polishing machine, or a dividing machine for grinding, polishing, or dividing, respectively, workpieces such as wafers, includes a chuck table that holds each workpiece and a processing unit that processes the workpiece held on the chuck table. The chuck table includes, for example, a porous member of a flat plate shape having a planar shape similar to the workpiece and a frame body with the porous member accommodated therein and exposed upwardly. Extending through the interior of the frame body, a suction channel is formed with one end thereof connected to the porous member, and the other end of the suction channel is to be connected to a suction source such as a suction pump.

When the workpiece is processed by the processing machine, processing fluid such as pure water is supplied to the workpiece and the processing unit, and processing debris that occurs during the processing is entrained in the processing fluid, and is removed. If workpieces are processed one after another by the processing machine, however, the processing fluid with such processing debris entrained therein is stuck to the chuck table. Hence, such processing debris has heretofore been removed from surfaces of the chuck table by bringing a cleaning tool such as a brush into contact with the rotating chuck table while rotating the cleaning tool with a motor. The processing debris may however penetrate into the porous member of the chuck table. In addition, when the chuck table is fabricated, the chuck table itself is ground from its upper surface, on which the workpieces are to be placed, to prepare the upper surface into a predetermined shape. Processing debris occurred in this grinding also penetrates into the porous member.

The processing debris penetrated into the porous member cannot be easily removed with the brush. If processing debris has penetrated into the porous member, the suction channel is blocked, so that the suction of the workpiece by the chuck table may become insufficient. When the processed workpiece is unloaded from the chuck table, on the other hand, water or air is caused to flow backward through the suction channel of the chuck table and is allowed to blow out of the porous member. As a consequence, a portion of the processing debris penetrated into the porous member also blows out and is stuck to the workpiece.

When a workpiece to be processed next is then placed on the chuck table, the processing debris which has blown out to the upper surface of the porous member is held between the workpiece and the chuck table, so that a clearance is formed between the workpiece and the chuck table. If the workpiece is processed in this state, the processing fluid enters from the clearance, so that the chuck table is further contaminated. Moreover, when the supply of the processing fluid is temporarily stopped, the processing fluid no longer enters, so that only air is drawn. As a result, the suction pressure of the chuck table varies substantially, leading to detection of a suction pressure error on the processing machine.

A cleaning apparatus has therefore been developed to remove processing debris penetrated into a chuck table (see JP 2011-200785A). This cleaning apparatus ejects a fluid mixture of high-pressure air and liquid to an upper surface of a chuck table.

### SUMMARY OF THE INVENTION

The mere ejection of the fluid mixture of high-pressure air and liquid to the chuck table is however unable to fully remove processing debris penetrated into the porous member and under the porous member, because the momentum of the fluid mixture is lost when it hits an upper portion of the porous member. In other words, the fluid mixture practically and effectively acts in only a small region. A cleaning method has hence been practiced conventionally. According to this cleaning method, water is caused to flow backward through the suction channel of the chuck table, and water is thus caused to blow out from the porous material, followed by suction through the suction channel. These steps are repetitively performed for approximately 50 hours, and the chuck table is then cleaned with a brush for five days. Even relying upon such an irksome method, and even spending such a long time, the debris penetrated into the chuck table cannot however be removed completely. Accordingly, the problem that a suction pressure error of a chuck table is frequently detected on a processing machine has not been sufficiently solved. Further, the problem that sticking of processing debris on workpieces unloaded from a processing machine is observed has not been sufficiently alleviated. There is also a need to incorporate, in a processing machine or the like, a configuration to eject a fluid mixture, so that an additional cost is required.

The present invention therefore has as objects thereof the provision of a cleaning jig and a cleaning method which can realize low-cost cleaning of a chuck table in a short time with high intensity and practical effectiveness.

In accordance with a first aspect of the present invention, there is provided a cleaning jig for cleaning a chuck table including a porous member that has a planar upper surface and a frame body with the porous member accommodated therein and exposed upwardly. The cleaning jig includes a main body having a front side, a back side, and a fluid supply passage extending from an inlet formed on the front side to an ejection orifice formed on the back side, a surface formed on the back side of the main body such that, when the cleaning jig is placed on the chuck table upon cleaning the chuck table, the surface faces the upper surface of the porous member, a groove formed around the ejection orifice on the back side of the main body, and a fluid drain passage that is formed through the main body and communicates with the groove.

Preferably, the cleaning jig may be further configured such that, when high-pressure fluid is ejected from the ejection orifice with the surface on the back side facing the upper surface of the porous member, a portion of the high-pressure fluid reaches a bottom portion of the porous member, and another portion of the high-pressure fluid flows between the main body and the porous member, reaches the groove, and is drained from the fluid drain passage.

In accordance with a second aspect of the present invention, there is provided a cleaning method for cleaning a chuck table including a porous member that has a planar upper surface and a frame body with the porous member accommodated therein and exposed upwardly. The cleaning method includes an arrangement step of arranging a cleaning jig that has an ejection orifice, such that the ejection orifice faces the porous member of the chuck table, an ejection step of ejecting high-pressure fluid from the ejection orifice, and a cleaning step of cleaning the chuck table by allowing the high-pressure fluid to reach a bottom portion of the porous member through the porous member.

Preferably, the high-pressure fluid may be at least one kind of fluid selected from the group consisting of water and air.

More preferably, in the cleaning step, the chuck table may draw the high-pressure fluid while the high-pressure fluid is ejected from the ejection orifice.

With the cleaning jig according to the first aspect of the present invention and in the cleaning step for the chuck table in the cleaning method according to the second aspect of the present invention, the high-pressure fluid is allowed to reach the bottom portion of the porous member. When the high-pressure fluid reaches the bottom portion of the porous member, the high-pressure fluid blows out from the lower surface of the porous member to a bottom of the frame body. The high-pressure fluid therefore acts on debris built up in the frame body, so that the debris is sufficiently removed. In addition, in a course along which the high-pressure fluid reaches the lower surface of the porous member, debris built up inside the porous member is also removed. With the cleaning jig according to the first aspect of the present invention and in the cleaning step for the chuck table in the cleaning method according to the second aspect of the present invention, the chuck table can be practically and effectively cleaned with high intensity as described above. As the high-pressure fluid is allowed to act on every corner of the chuck table, it is also possible to sufficiently remove debris by cleaning in a short period of time and hence to lower the cost required for cleaning.

The cleaning jig and the cleaning method provided by the first and second aspects of the present invention can therefore realize low-cost cleaning of the chuck table in a short time with high intensity and practical effectiveness.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view schematically illustrating a chuck table to be cleaned by a cleaning jig according to an embodiment of a first aspect of the present invention and a cleaning method according to an embodiment of a second aspect of the present invention;

FIG. 1B is a cross-sectional view that is taken along line IB-IB of FIG. 1A and schematically illustrates the chuck table;

FIG. 2A is a perspective view schematically illustrating a front side of a main body of the cleaning jig;

FIG. 2B is a perspective view schematically illustrating a back side of the main body of the cleaning jig;

FIG. 3A is a plan view schematically illustrating the back side of the main body of the cleaning jig;

FIG. 3B is a cross-sectional view that is taken along line IIIB-IIIB of FIG. 3A and schematically illustrates a cross-section of the cleaning jig;

FIG. 3C is a cross-sectional view that is taken along line IIIC-IIIC of FIG. 3A and schematically illustrates another cross-section of the cleaning jig;

FIG. 4 is a perspective view schematically illustrating an arrangement step in the cleaning method;

FIG. 5 is a fragmentary cross-sectional view schematically illustrating a cleaning method according to prior art;

FIG. 6 is a fragmentary cross-sectional view that is taken along VI-VI line of FIG. 4 and schematically illustrates an ejection step and a cleaning step in the cleaning method according to the embodiment during cleaning of the chuck table;

FIG. 7 is a fragmentary cross-sectional view that is taken along VII-VII line of FIG. 1A and schematically illustrates, on an enlarged scale, a bottom portion of a porous member and a frame body in the chuck table during cleaning of the chuck table by the cleaning method according to the embodiment; and

FIG. 8 is a flow chart illustrating a flow of individual steps of the cleaning method according to the embodiment for the chuck table.

### DETAILED DESCRIPTION OF THE PREFERRED EMBODIMENTS

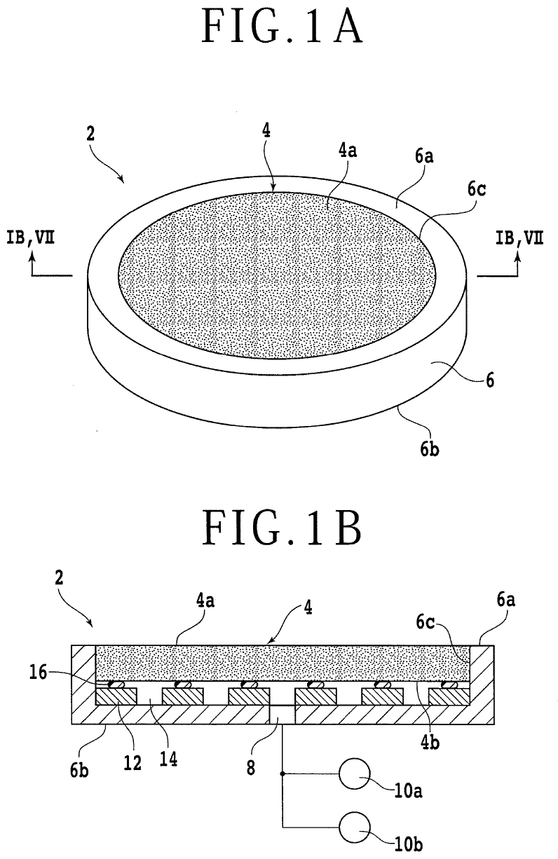

With reference to the attached drawings, an embodiment of a first aspect of the present invention and an embodiment of a second aspect of the present invention will hereinafter be described in detail. A description will first be made with regard to the manner of use of a chuck table which is to be cleaned by a cleaning jig and a cleaning method according to the respective embodiments. FIG. 1A is a perspective view schematically illustrating the chuck table, denoted by 2. The chuck table 2 is arranged in a processing machine that processes a workpiece such as a semiconductor wafer. The chuck table 2 is used to hold the workpiece by suction. The processing machine processes the workpiece held by suction on the chuck table 2.

The workpiece is, for example, a wafer formed with a material such as silicon, silicon carbide (SiC), or any other semiconductor material, or a substantially disk-shaped substrate made from such a material as sapphire, glass, or quartz. The workpiece is divided on a front surface thereof into a plurality of regions by a plurality of planned dividing lines (streets) arrayed in a grid pattern, and devices such as LCs or LSI circuits are formed in the respective regions. Finally, the workpiece is divided along the streets, so that individual device chips are formed. The workpiece is ground on a back surface thereof, and hence is thinned. On the back surface of the workpiece thus ground, minute irregularities called “grinding marks” are formed. If the device chips are manufactured by dividing the workpiece as it is along the streets, such minute irregularities remain on the device chips, thereby causing a reduction in the flexural strength of the device chips. Therefore, the workpiece the back surface of which has been ground is polished on a back side thereof, thereby removing the minute irregularities on the back surface and planarizing the back surface. Then, no minute irregularities remain on the device chips.

The chuck table 2 is incorporated and used in a processing machine such as a dividing machine for dividing workpieces, a grinding machine for grinding workpieces, or a polishing machine for polishing workpieces. These various processing machines each hold each workpiece by suction on the chuck table 2, and each process the workpiece held on the chuck table 2.

A description will next be made with regard to the chuck table 2. FIG. 1B is a cross-sectional view that is taken along line IB-IB of FIG. 1A and schematically illustrates the chuck table 2. The chuck table 2 includes a porous member 4, which has a planar upper surface 4a, and a frame body 6 with the porous member 4 accommodated therein and exposed upwardly. The porous member 4 is a plate-shaped porous member formed with such a material as ceramics. The planar shape and size of the porous member 4 are appropriately designed according to the planar shape and size of the workpiece to be processed by the processing machine. If the workpiece has a disk shape, the porous member 4 is also designed to have a disk shape. On a side of an upper surface 6a of the frame body 6, a recessed accommodation portion 6c is formed. The recessed accommodation portion 6c can accommodate the porous member 4 therein. In a bottom part of the recessed accommodation portion 6c, a base member 12 is arranged to support the porous member 4. The recessed accommodation portion 6c is substantially identical in shape and size to the porous member 4. The porous member 4 is fixed to the frame body 6 in a state in which it is accommodated in the recessed accommodation portion 6c of the frame body 6 and is supported on the base member 12. When the porous member 4 is accommodated in the frame body 6, the upper surface 4a of the porous member 4 is upwardly exposed. This upper surface 4a of the porous member 4 serves as a holding surface of the chuck table 2.

Through the interior of the frame body 6, a suction channel 8 is formed to communicate a lower surface 6b of the frame body 6 and the recessed accommodation portion 6c with each other. The suction channel 8 branches into a plurality of branch passages 14 below the recessed accommodation portion 6c, and the individual branch passages 14 communicate to different locations in the bottom part of the recessed accommodation portion 6c. The suction channel 8 and the branch passages 14 are surrounded by the base member 12.

To the suction channel 8 communicating with the lower surface 6b of the frame body 6, a suction source 10a is connected. The suction source 10a is disposed in the processing machine where the chuck table is arranged, a factory where the processing machine is installed, or the like. The suction source 10a is configured, for example, of a vacuum pump, an ejector, or the like. When the workpiece is placed on the upper surface 4a of the porous member 4 and the suction source 10a is actuated, a negative pressure generated at the suction source 10a acts on the workpiece through the suction channel 8, the individual branch passages 14, and the porous member 4. Then, the workpiece is held by suction on the chuck table 2.

To the suction channel 8 exposed on the lower surface 6b of the frame body 6, a fluid supply source 10b may be connected instead. The fluid supply source 10b is also disposed in the processing machine where the chuck table 2 is arranged, a factory where the processing machine is installed, or the like. After the workpiece held on the chuck table 2 has been processed, the workpiece may be stuck to the chuck table 2, and therefore may hardly be unloaded. If this is the case, the fluid supply source 10b is actuated to cause fluid such as water to flow backward from the suction channel 8 or the like, so that the fluid is allowed to blow out of the upper surface 4a of the porous member 4. As a consequence, the workpiece floats up, so that the unloading of the workpiece from the chuck table 2 is facilitated. Further, the fluid supply source 10b may also be used for purposes other than the unloading of the workpiece from the chuck table 2. If the fluid supply source 10b is actuated when no workpiece is placed on the chuck table 2, for example, a portion of dust penetrated into the porous member 4 can be blown out to a side of the upper surface 4a. It is however difficult for this method to discharge dust and the like in their entirety outside the porous member 4.

When the chuck table 2 is fabricated with the porous member 4 accommodated in the recessed accommodation portion 6c, the porous member 4 is fixed to the base member 12 with a bonding material 16. The porous member 4 and the frame body 6 are then ground and planarized at the upper surface 4a and upper surface 6a thereof to a uniform height. Here, processing debris occurs, and penetrates into the interior of the porous member 4. Further, when the workpiece is processed by the processing machine, processing fluid such as pure water is supplied to the workpiece and a processing unit, and processing debris which occurs during the processing is entrained and removed in the processing fluid. If workpieces are processed one after another by the processing machine, however, the processing fluid with processing debris entrained therein is stuck to the chuck table 2, and a portion of the processing debris penetrates into the porous member 4.

Hence, the chuck table 2 is cleaned by the cleaning jig and the cleaning method according to these embodiments, whereby the debris incorporated into the interior of the chuck table 2 is removed. A description will next be made with regard to the cleaning jig according to this embodiment.

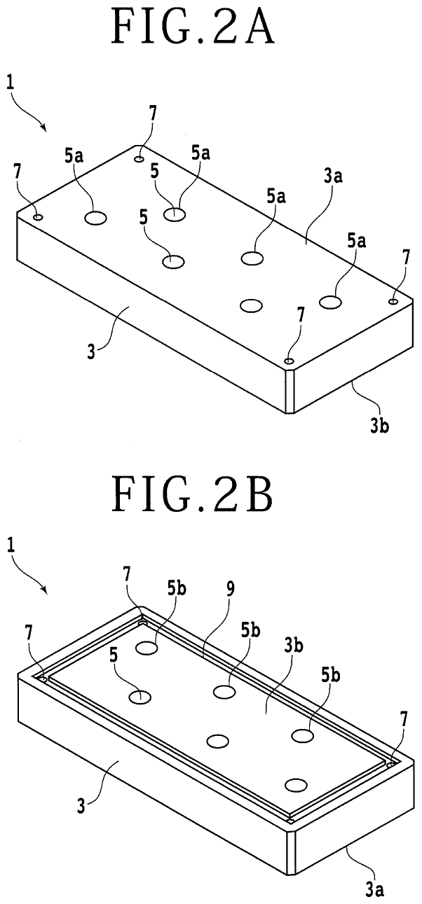

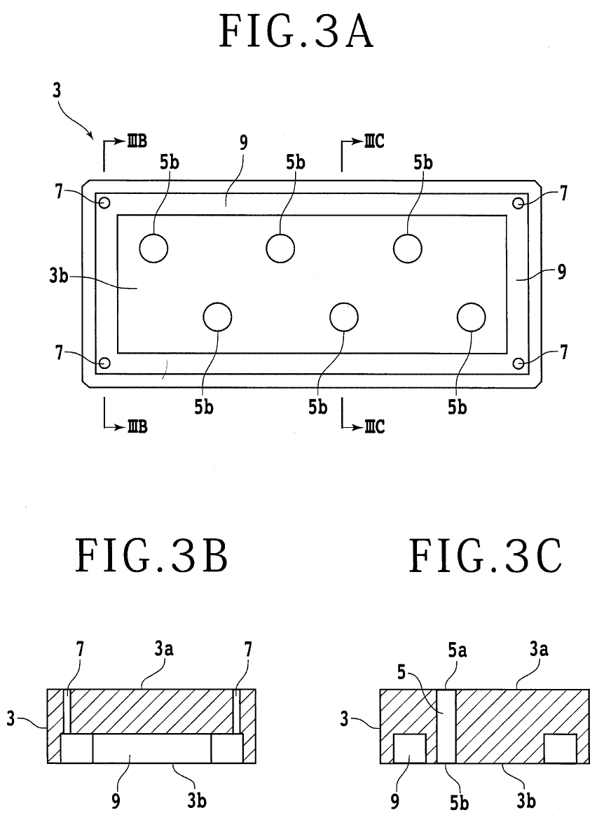

FIG. 2A is a perspective view schematically illustrating a front side 3a of a main body 3 of the cleaning jig, denoted by 1, and FIG. 2B is a perspective view schematically illustrating a back side 3b of the main body 3 of the cleaning jig 1. FIG. 3A is a plan view schematically illustrating the back side 3b of the main body 3 of the cleaning jig 1, and FIGS. 3B and 3C are cross-sectional views that are taken along lines IIIB-IIIB and IIIC-IIIC, respectively, of FIG. 3A and schematically illustrate different cross-sections of the main body 3 of the cleaning jig 1. Extending through the main body 3 of the cleaning jig 1, fluid supply passages 5 are formed extending from inlets 5a, which are formed on the front side 3a, to ejection orifices 5b, which are formed on the back side 3b, respectively.

The main body 3 is formed from such a material as an acrylonitrile-butadiene-styrene (ABS) resin, an acrylate-styrene-acrylonitrile (ASA) resin, a polypropylene (PP) resin, an epoxy-based resin, or an acrylic resin. The material of the main body 3 is however not limited to these materials. The main body 3 is fabricated by a three-dimensional (3D) printer, an injection molding machine, or the like. As an alternative, the main body 3 may also be fabricated by removing unnecessary portions from a block formed with a resin material. The fabrication method of the main body 3 is however not limited to these methods.

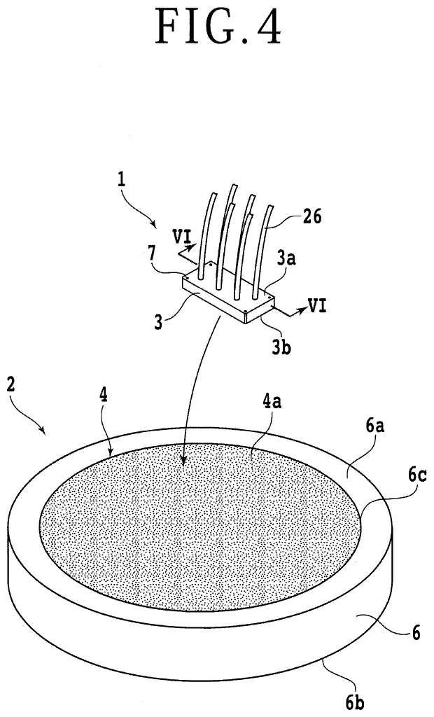

In the main body 3, a single or a plurality of the fluid supply passages 5 is formed, and a single or a plurality of the inlets 5a and a single or a plurality of the ejection orifices 5b are also formed corresponding to the individual fluid supply passage or passages 5. In FIGS. 2A through 3C, the main body 3 is schematically illustrated taking as an example a case in which as many as six of the fluid supply passages 5 are formed. The number of the fluid supply passages 5 is however not limited to this case. The number of the fluid supply passage or passages 5 may be determined, for example, according to the number of high-pressure fluid supply system or systems (not illustrated) disposed in the processing machine or the like for which the cleaning jig 1 is used. To the inlets 5a of the respective fluid supply passages 5, the individual high-pressure fluid supply systems may be connected via tubes 26 (see FIG. 4), respectively. If desired to practically and effectively clean the chuck table 2, the connection of as many high-pressure fluid supply systems as possible to the cleaning jig 1 is desired. Therefore, the number of the fluid supply passages 5 to be formed in the cleaning jig 1 is preferably determined based on the number of high-pressure fluid supply systems that are connectable to the cleaning jig 1.

Here, no particular limitation is imposed on the arrangement of the inlets 5a on the front side 3a of the main body 3. Desirably, however, the inlets 5a may be arranged as close to one another as possible in distance. It is however necessary that, when one of the tubes 26 has been connected to one of the inlet 5a, the connection of another one of the tubes 26 to another one of the inlets 5a is not interfered with. It is therefore necessary for the mutually adjacent inlets 5a to be apart from one another by a distance which is needed to connect the tubes 26 or longer.

The main body 3 has a planar surface on the back side 3b. When the cleaning jig 1 is placed on the chuck table 2 upon cleaning of the chuck table 2 with the cleaning jig 1, this planar surface on the back side 3b of the main body 3 faces the upper surface 4a of the porous member 4. On the back side 3b of the main body 3, the ejection orifices 5b are formed as many as the number of the fluid supply passages 5. If the fluid supply passages 5 are formed along a shortest distance from the front side 3a to the back side 3b, the arrangement of the ejection orifices 5b on the back side 3b is mirror-inverted to that of the inlets 5a on the front side 3a. The arrangement of the ejection orifices 5b is however not limited to the above-mentioned arrangement. It is to be noted that the fluid supply passages 5 which extend through the main body 3 are not required to be straight, but may curve along their extension from the inlets 5a to the ejection orifices 5b. In other words, the arrangement of the ejection orifices 5b is not required to correspond to that of the inlets 5a, and may be determined irrespective of that of the inlets 5a.

A groove 9 is formed around the ejection orifices 5b on the back side 3b of the main body 3. For example, the groove 9 is formed along an outer periphery of the back side 3b of the main body 3, and surrounds all the ejection orifices 5b on the back side 3b of the main body 3. Here, it is to be noted that, on the back side 3b of the main body 3, the respective ejection orifices 5b are not in contact with the groove 9. The width and depth of the groove 9 are not limited, and are appropriately determined insofar as the grooves 9 can exhibit a function to be mentioned below. Through the main body 3, fluid drain passages 7 are formed in communication with the groove 9. Each fluid drain passage 7 communicates at one end thereof with the groove 9, and at the other end thereof with the front side 3a of the main body 3. No particular limitation is imposed the number of the fluid drain passages 7 formed through the main body 3. If the main body 3 has a box shape or a parallelepiped shape, for example, the main body 3 has a substantially rectangular shape on the back side 3b. In this case, the groove 9 is formed in a rectangular form along the outer periphery of the back side 3b. Further, the fluid drain passages 7 are formed in corner parts of the groove 9. However, the form of the groove 9 and the positions of the fluid drain passages 7 are not limited to these form and positions.

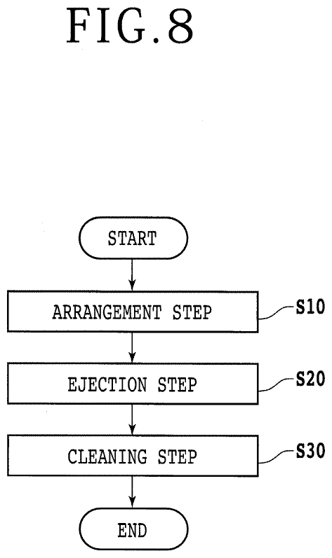

FIG. 4 is a perspective view schematically illustrating an arrangement step S10 (see FIG. 8) of the cleaning method according to this embodiment. If the cleaning jig 1 is used for the processing machine or the like, the tubes 26 are connected to the inlets 5a of the fluid supply passages 5 as illustrated in FIG. 4. On the other hand, no connection is made to the fluid drain passages 7 on the front side 3a of the main body 3, so that the fluid drain passages 7 are open to the air. However, an unillustrated suction source may be connected to the fluid drain passages 7.

A description will next be made with regard to the cleaning method according to this embodiment. The cleaning method according to this embodiment is a method that cleans the chuck table 2 to remove debris, and is performed by using, for example, the cleaning jig 1 illustrated in FIGS. 2A to 4 and FIG. 6. In other words, the following description illustrates a method of using the cleaning jig 1 according to this embodiment.

FIG. 8 is a flow chart illustrating a flow of the arrangement step S10, an ejection step S20, and a cleaning step S30 of the cleaning method according to this embodiment. In the cleaning method according to this embodiment, the arrangement step S10 is first performed to arrange the cleaning jig 1, which has the ejection orifices 5b, such that the ejection orifices 5b face the porous member 4 of the chuck table 2. Before the arrangement step S10 is performed, the tubes 26 are connected at one ends thereof to the respective inlets 5a beforehand as illustrated in FIG. 4. The tubes 26 are connected at the other ends thereof to an unillustrated high-pressure fluid supply system that can supply one or both of water and air at high pressure. Preferably, the high-pressure fluid supply system can supply high-pressure water as cleaning fluid.

In the arrangement step S10, the cleaning jig 1 is placed on the porous member 4 while the planar surface on the back side 3b of the main body 3 of the cleaning jig 1 is maintained to face the upper surface 4a of the porous member 4. For example, an operator holds the cleaning jig 1 in hand, and positions the cleaning jig 1 over the porous member 4. At this time, the cleaning jig 1 may be in contact with the porous member 4, or the cleaning jig 1 may slightly float from the porous member 4.

Next, the ejection step S20 is performed to eject the high-pressure fluid from the ejection orifices 5b. Described specifically, the high-pressure fluid supply source is actuated to supply the high-pressure fluid to the inlets 5a of the fluid supply passages 5 through the tubes 26. Then, the high-pressure fluid flows through the fluid supply passages 5, reaches the ejection orifices 5b, and blows out downward of the main body 3 from the ejection orifices 5b.

It is to be noted that, in the cleaning method according to this embodiment, the arrangement step S10 may be performed later than the ejection step S20. If this is the case, the cleaning jig 1 that ejects the high-pressure fluid from the ejection orifices 5b is placed on the porous member 4 of the chuck table 2. As the high-pressure fluid hits the porous member 4 and spreads around at this time, it is preferred to perform the ejection step S20 after the arrangement step S10.

Here, the high-pressure fluid that blows out of the ejection orifices 5b has a pressure higher than the atmospheric pressure. The pressure of the high-pressure fluid may be set, for example, at equal to 2 atm or higher and equal to 5 atm or lower. If the processing machine or the like is provided with a high-pressure fluid supply system for any particular purpose, fluid the pressure of which has been regulated for the particular purpose may be supplied as it is to the cleaning jig 1. Preferably, the pressure of the fluid that is supplied to the cleaning jig 1 and is ejected from the ejection orifices 5b is approximately 3 atm. However, the pressure of the fluid is not limited to this pressure. The flow rate of the fluid that blows out of the ejection orifices 5b may be set, for example, at equal to or higher than 10 L/min and equal to or lower than 30 L/min. If the processing machine or the like is provided with a high-pressure fluid supply system for any particular purpose, fluid is preferably supplied at a maximum flow rate available from the supply source. The greater the amount of the fluid to be ejected from the ejection orifices 5b is, the more practically and effectively the chuck table 2 can be cleaned. Preferably, the flow rate of the high-pressure fluid is set at approximately 20 L/min.

When the arrangement step S10 and the ejection step S20 are performed, the high-pressure fluid ejected from the ejection orifices 5b flows into the porous member 4, so that the chuck table 2 is cleaned. A description will next be made with regard to the cleaning step S30, in which the high-pressure fluid is allowed to reach a bottom portion of the porous member 4 through the porous member 4 and clean the chuck table 2.

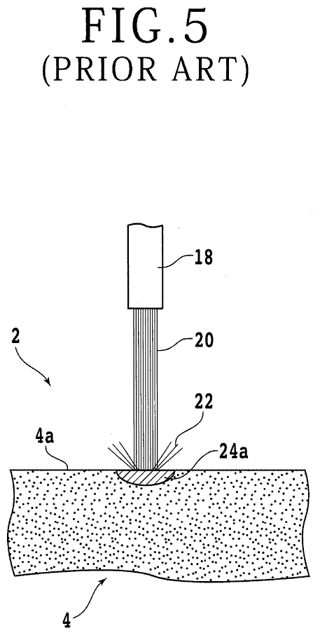

For the sake of a comparison, an example of the cleaning of a chuck table 2, the cleaning having been performed to date, will be described first. FIG. 5 is a cross-sectional view schematically illustrating how the cleaning of the chuck table 2 has heretofore been performed. The cleaning of the chuck table 2 has heretofore been performed by positioning an ejection nozzle 18 above a porous member 4 of the chuck table 2 and ejecting a high-pressure fluid mixture 20 of water and air from the ejection nozzle 18 toward an upper surface 4a of the porous member 4.

The fluid mixture 20 ejected from the ejection nozzle 18 travels in the air, and hits the upper surface 4a of the porous member 4. The porous member 4 receives a strong impact at this time. Nonetheless, a portion of the fluid mixture 20 scatters around without penetrating into the porous member 4. Scattering fluid 22 is schematically illustrated in FIG. 5. Another portion of the fluid mixture 20 which has penetrated into the porous member 4, quickly loses its momentum, and turns to simple water of the atmospheric pressure. A range in which the high-pressure fluid mixture 20 acts in its form is therefore only an extremely limited range in a neighborhood of the upper surface 4a of the porous member 4. In FIG. 5, a region 24a in which the high-pressure fluid mixture 20 practically and effectively cleans the porous member 4 is schematically indicated by hatching. Regions of the porous member 4 which are distant from the upper surface 4a are not cleaned practically and effectively, so that debris and the like are prone to remain there.

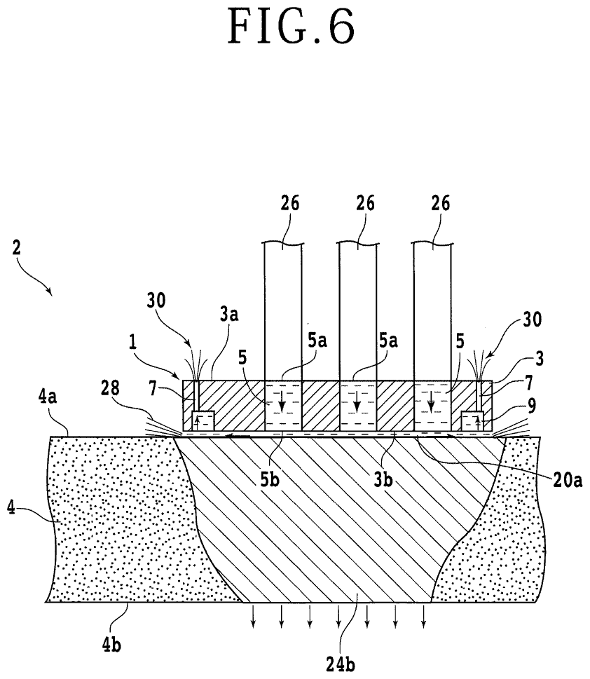

Moreover, the water of the atmospheric pressure simply drips from a lower surface 4b (see FIG. 6) of the porous member 4 in the method of the prior art. The high-pressure fluid mixture 20 does not reach the base member 12, the suction channel 8, the branch passages 14, and the like, all of which are illustrated in FIG. 1B and are arranged in a bottom part of the recessed accommodation portion 6c of the frame body 6 of the chuck table 2, so that they are not cleaned sufficiently.

Further, when the suction source 10a connected to the suction channel 8 is actuated upon cleaning of the chuck table 2, the generated negative pressure leaks in regions of the porous member 4 which are other than the region where the fluid mixture 20 ejected from the ejection nozzle 18 hits the porous member 4. The water in which the negative pressure generated at the suction source 10a has lost its momentum is not allowed to restore practical and effective cleaning power accordingly.

In particular, debris is prone to build up around the bonding material 16 with which the base member 12 and the porous member 4 are bonded together, and is hardly removed. When the workpiece is unloaded from the chuck table 2, the fluid supply source 10b is actuated to cause the fluid such as water to blow out of the upper surface 4a of the porous member 4. At this time, a portion of the debris built up around the bonding material 16 and in the porous member 4 is entrained in the fluid. Such debris is then stuck to the workpiece when the fluid is caused to blow out of the upper surface 4a of the porous member 4.

In contrast, in the cleaning step S30 of the cleaning method according to this embodiment, the high-pressure fluid is allowed to reach the bottom portion of the porous member 4 and then blow out from the lower surface 4b of the porous member 4 to the bottom part of the recessed accommodation portion 6c of the frame body 6. FIG. 6 is a fragmentary cross-sectional view that is taken along VI-VI line of FIG. 4 and schematically illustrates the ejection step S20 and the cleaning step S30. The cleaning step S30 will next be described in detail.

In the cleaning step S30, high-pressure fluid 20a ejected from the ejection orifices 5b of the cleaning jig 1 is supplied to a slight clearance between the main body 3 of the cleaning jig 1 and the upper surface 4a of the porous member 4. Then, a portion of the high-pressure fluid 20a flows, in a direction away from the ejection orifices 5b, along the upper surface 4a of the porous member 4 through the clearance, and another portion of the high-pressure fluid 20a flows into the interior of the porous member 4. At this time, the high-pressure fluid 20a is confined in the main body 3 of the cleaning jig 1 and is kept out of contact with the air, and therefore hardly undergoes a reduction in pressure. Accordingly, the high-pressure fluid 20a which flows inside the porous member 4 flows toward the lower surface 4b while substantially maintaining its pressure. In the course of this flow, the high-pressure fluid 20a acts on debris and the like contained in the porous member 4, so that the debris and the like are removed. In FIG. 6, a region 24b in which the high-pressure fluid 20a practically and effectively cleans the porous member 4 is schematically indicated by hatching. While maintaining the practical and effective pressure, the high-pressure fluid 20a then reaches the lower surface 4b of the porous member 4.

Described from a different viewpoint, the cleaning jig 1 suppresses, with the main body 3, the high-pressure fluid 20a from undergoing a reduction in pressure. Numerous pores included in the porous member 4 therefore function by themselves as conduction paths for the high-pressure fluid 20a, and allow the high-pressure fluid 20a to be conducted to the lower surface 4b. The high-pressure fluid 20a hence blows out downwardly from the lower surface 4b of the porous member 4.

The high-pressure fluid 20a which reaches the bottom portion of the porous member 4 is however not needed to completely retain its pressure when it was ejected from the ejection orifices 5b. If the pressure of the high-pressure fluid 20a which reaches the bottom portion of the porous member 4 is higher than the atmospheric pressure, the cleaning method according to this embodiment can clean the chuck table 2 more actively than the method of the prior art. Obviously, the smaller the pressure loss of the high-pressure fluid 20a is, the more practically and effectively the chuck table 2 is cleaned.

As described above, when the back side 3b of the main body 3 is positioned to face the porous member 4 and the high-pressure fluid 20a is ejected from the ejection orifices 5b, a portion of the high-pressure fluid 20a reaches the bottom portion of the porous member 4. On the other hand, another portion of the high-pressure fluid 20a, the another portion having not flowed into the porous member 4 after the ejection from the ejection orifices 5b, flows between the surface on the back side 3b of the main body 3 and the upper surface 4a of the porous member 4, and reaches the groove 9. This another portion of the high-pressure fluid 20a flows through the groove 9 to the fluid drain passages 7, and is then drained as high-pressure fluid 30 from the fluid drain passages 7 to the front side 3a of the main body 3.

In addition, a further portion of the high-pressure fluid 20a, the further portion having not flowed into the porous member 4, does not enter even the groove 9, flows as it is on the upper surface 4a of the porous member 4, and blows out, as high-pressure fluid 28, of the clearance between the main body 3 and the porous member 4. In FIG. 6, the high-pressure fluid 28 and the high-pressure fluid 30 which are blowing out of the main body 3 are schematically illustrated. The high-pressure fluid 28 and the high-pressure fluid 30 come into contact with the air for the first time at this time, and are quickly and progressively reduced in pressure. It is to be noted that the high-pressure fluid which did not flow into the porous member 4 acts to maintain an adequate interval between the main body 3 and the porous member 4. The main body 3 is hence not worn through its contact with the porous member 4, thereby avoiding the occurrence or the like of debris which would otherwise arise due to wearing of the main body 3. For example, any attempt to make the high-pressure fluid 20a which has been ejected from the ejection orifices 5b flow in its entirety into the porous member 4 leads to a large repulsive force in association with the ejection of the high-pressure fluid 20a from the ejection orifices 5b, whereby the main body 3 unstably and significantly floats up. In this case, the main body 3 and the porous member 4 are significantly spaced apart from each other, so that the high-pressure fluid 20a which will flow to the porous member 4 is prone to undergo a reduction in pressure. If the high-pressure fluid 20a does not flow in its entirety into the porous member 4 and portions of the high-pressure fluid 20a are allowed to drain as the high-pressure fluid 28 and the high-pressure fluid 30, on the other hand, the clearance between the main body 3 and the porous member 4 is appropriately retained.

If the groove 9 and the fluid drain passages 7 are not formed in the main body 3 of the cleaning jig 1, the fluid 28 blows out with an extremely strong momentum from the clearance between the main body 3 and the porous member 4 into the air. The fluid 28 then scatters around the chuck table 2. As a result, the fluid 28 contaminates surroundings and, in addition, is also blown to the operator, resulting in poor workability. If the groove 9 and the fluid drain passages 7 are formed in the main body 3 of the cleaning jig 1, on the other hand, the high-pressure fluid 20a is adequately drained as the high-pressure fluid 30 from the fluid drain passages 7, thereby enabling to suppress the momentum of the high-pressure fluid 28 that scatters to the outside from the clearance between the main body 3 and the porous member 4.

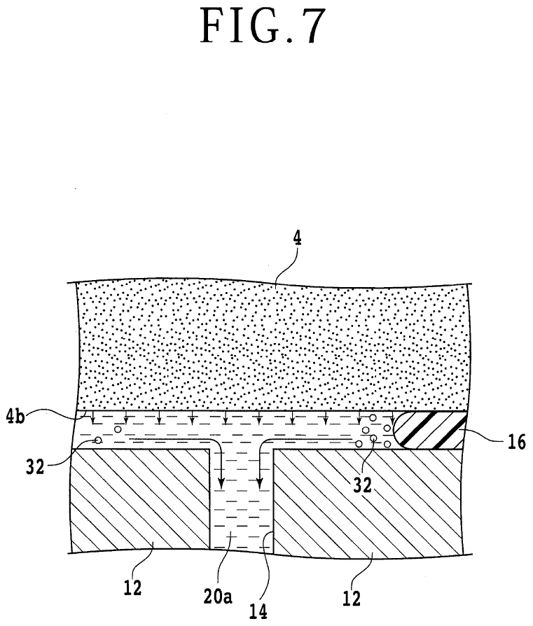

Reference is next had to FIG. 7. FIG. 7 is a fragmentary cross-sectional view that is taken along VII-VII line of FIG. 1A and schematically illustrates, on an enlarged scale, the bottom portion of the porous member 4 and the frame body 6 of the chuck table 2 during cleaning of the chuck table 2. In FIG. 7, the high-pressure fluid 20a ejected downwardly from the lower surface 4b of the porous member 4 in the bottom part of the recessed accommodation portion 6c of the frame body 6 is schematically illustrated. The high-pressure fluid 20a ejected downwardly from the lower surface 4b actively removes debris 32 built up below the porous member 4. The debris 32 is prone to build up especially around the bonding material 16, and this problem has remained as a cause of various troubles. In the cleaning step S30, the high-pressure fluid 20a then acts on the debris 32 to wash it away, whereby the high-pressure fluid 20a with the debris 32 contained therein is drawn into the suction source 10a through the branch passages 14 and the suction channel 8 (see FIG. 1B). Therefore, the chuck table 2 is cleaned extremely actively.

In the cleaning step S30, with the cleaning jig 1 being held in hand, the operator moves the cleaning jig 1 over the upper surface 4a of the porous member 4. As the main body 3 of the cleaning jig 1 slightly floats up owing to the ejection of the high-pressure fluid 20a from the ejection orifices 5b at this time, the cleaning jig 1 slidingly moves without contact to the upper surface 4a of the porous member 4. Therefore, the movement of the cleaning jig 1 is smooth, and moreover, the problem that otherwise, the main body 3 would come into contact with the porous member 4 and ground debris would occur is avoided. The operator repetitively moves the cleaning jig 1 over the entire area of the upper surface 4a of the porous member 4. As a consequence, the high-pressure fluid 20a is supplied to every part of the porous member 4, and the chuck table 2 is cleaned in every part. When the chuck table 2 is cleaned with use of the cleaning jig 1, the chuck table 2 can easily be cleaned in an extremely short period of time.

According to the above-described cleaning method practiced to date, for example, water is caused to flow backward through the suction channel 8 of the chuck table 2, and is thus ejected from the upper surface 4a of the porous member 4, followed by suction through the suction channel 8. These steps are repetitively performed for approximately 50 hours, and the chuck table 2 is then cleaned with a brush for five days. Even relying upon such an irksome method, and even spending such a long time, the debris penetrated into the chuck table 2 cannot however be removed completely. According to the cleaning method using the cleaning jig 1, on the other hand, the debris penetrated into the chuck table 2 can be removed substantially completely by simply performing the cleaning step S30 for approximately 10 minutes while moving the cleaning jig 1. The frequency of occurrence of a suction pressure error on the chuck table 2 as caused by debris therefore drastically decreases in the processing machine. A drastic decrease is also observed in the amount of debris that is stuck to a workpiece when, after processing of the workpiece held on the chuck table 2, water is caused to flow backward through the suction channel 8 and is allowed to blow out of the upper surface 4a of the porous member 4.

According to the cleaning jig 1 of this embodiment and the cleaning method of this embodiment, the chuck table 2 can be practically and effectively cleaned with high intensity as described above. Therefore, substantially no debris remains on or in the chuck table 2, and any inconvenience caused by remaining debris can be suppressed. Moreover, the time required to clean the chuck table 2 is significantly shortened, and the amount of the high-pressure fluid 20a to be used for cleaning is reduced by an amount corresponding to the time thus saved. The cleaning cost is hence extremely reduced.

The cleaning jig 1 is totally different in cleaning effects and operation mechanism from brushes heretofore used to clean such chuck tables, but similar to the brushes, cleans the chuck table 2 while moving over the upper surface 4a of the porous member 4. The cleaning jig 1 can hence be also called a “Water Brush.” However, the configuration and the manner of use of the cleaning jig 1 should not be restricted based on this product name.

It is to be noted that the present invention is not limited to the details of the above-described embodiments and can be practiced with various modifications. In the embodiments described above, the description is made taking as an example the case in which the high-pressure fluid 20a supplied to the cleaning jig 1 through the tubes 26 and ejected from the ejection orifices 5b is water. However, the embodiments of the present invention are not limited to the above-mentioned case. The high-pressure fluid 20a may be air. The high-pressure fluid 20a may also be a fluid mixture of water and air. If air is contained in the high-pressure fluid 20a, the high-pressure fluid 20a can be provided with a still higher pressure. If no air is contained in the high-pressure fluid 20a, on the other hand, the high-pressure fluid 20a is less prone to reductions in pressure while flowing in the porous member 4.

In the embodiments described above, the description is also made with regard to the case in which the high-pressure fluid 20a is supplied from the supply system which is disposed in the processing machine or factory equipment and which is used for a different purpose, to the cleaning jig 1 through the tubes 26. The description is also made with regard to the case in which the cleaning of the chuck table 2 with the cleaning jig 1 is performed primarily by manual work of the operator. However, the embodiments of the present invention are not limited to these cases. Described specifically, the processing machine may be provided with a dedicated cleaning system including the cleaning jig 1 and a dedicated supply system, such that the chuck table 2 can swiftly be cleaned at a desired timing. Further, this cleaning system may include a moving mechanism to move the cleaning jig 1 over the upper surface 4a of the porous member 4, and the processing machine may automatically perform cleaning of the chuck table 2 by this cleaning system. In this case, it is unnecessary to switch the connection between the fluid supply systems by manual work or to open a processing chamber of the processing machine by an operator. Accordingly, the cleaning work of the chuck table 2 can be performed with less effort in a short period of time, no contaminant penetrates into the processing chamber from the outside, and neither debris nor the fluid used for the cleaning spreads from the processing chamber to the outside.

In the embodiments described above, the description is made with regard to the case in which the six fluid supply passages 5 are formed in the main body 3 of the cleaning jig 1 and the six tubes 26 are connected to the cleaning jig 1. However, the embodiments of the present invention are not limited to this case. For example, one fluid supply passage 5 may be formed in the cleaning jig 1, and one tube 26 may be connected to the cleaning jig 1. Also in this case, the high-pressure fluid 20a is allowed to flow to the bottom portion of the porous member 4 because the main body 3 covers around all the ejection orifices 5b on the back side 3b of the main body 3.

In the embodiments described above, the description is also made with regard to the case in which the back side 3b of the main body 3 of the cleaning jig 1 is the planar surface. However, the embodiments of the present invention are not limited to this case. In other words, the back side 3b of the main body 3 is not required to be strictly planar, and the main body 3 may have irregularities on the back side 3b. Insofar as the cleaning jig 1 is configured such that the main body 3 comes closer to the porous member 4 at a region outside the groove 9 on the back side 3b than the other region, for example, when the cleaning jig 1 is arranged on the upper surface 4a of the porous member 4, the high-pressure fluid 20a hardly comes into contact with the air, and can hence be suppressed from being reduced in pressure.

The cleaning of the chuck table 2 may be performed when the chuck table 2 is installed in the processing machine. The cleaning of the chuck table 2 may also be performed outside the processing machine on the chuck table 2 uninstalled from the processing machine.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A cleaning jig for cleaning a chuck table including a porous member that has a planar upper surface and a frame body with the porous member accommodated therein and exposed upwardly, the cleaning jig comprising:
a main body having a front side, a back side, and a fluid supply passage extending from an inlet formed on the front side to an ejection orifice formed on the back side;
a surface formed on the back side of the main body such that, when the cleaning jig is placed on the chuck table upon cleaning the chuck table, the surface faces the upper surface of the porous member;
a groove formed around the ejection orifice on the back side of the main body; and
a fluid drain passage that is formed through the main body and communicates with the groove.

2. The cleaning jig according to claim 1, further configured such that, when high-pressure fluid is ejected from the ejection orifice with the surface on the back side facing the upper surface of the porous member, a portion of the high-pressure fluid reaches a bottom portion of the porous member, and another portion of the high-pressure fluid flows between the main body and the porous member, reaches the groove, and is drained from the fluid drain passage.

3. A cleaning method for cleaning a chuck table including a porous member that has a planar upper surface and a frame body with the porous member accommodated therein and exposed upwardly, the cleaning method comprising:
an arrangement step of arranging a cleaning jig that has an ejection orifice, such that the ejection orifice faces the porous member of the chuck table;
an ejection step of ejecting high-pressure fluid from the ejection orifice; and
a cleaning step of cleaning the chuck table by allowing the high-pressure fluid to reach a bottom portion of the porous member through the porous member.

4. The cleaning method according to claim 3, wherein the high-pressure fluid is at least one kind of fluid selected from the group consisting of water and air.

5. The cleaning method according to claim 3, wherein, in the cleaning step, the chuck table draws the high-pressure fluid while the high-pressure fluid is ejected from the ejection orifice.
